(19) United States
(12) Patent Application Publication
(10) Pub. No.: US 2024/0383757 A1
(43) Pub. Date: Nov. 21, 2024

(54) METHODS FOR THE GROWTH OF A GRAPHENE LAYER STRUCTURE ON A SUBSTRATE AND AN OPTO-ELECTRONIC DEVICE

(71) Applicant: Paragraf Limited, Somersham (GB)

(72) Inventors: Sebastian Dixon, Somersham (GB); Ivor Guiney, Somersham (GB); Simon Thomas, Somersham (GB)

(73) Assignee: Paragraf Limited, Somersham (GB)

(21) Appl. No.: 18/687,410

(22) PCT Filed: Aug. 23, 2022
(86) PCT No.: PCT/EP2022/073424

§ 371 Date: Feb. 28, 2024

(30) Foreign Application Priority Data
Sep. 1, 2021 (GB) 2112453.2

(51) Int. Cl. C01B 32/186; C23C 16/02; C23C 16/26; C23C 16/46; H01L 21/02; H01L 31/18; H01L 33/00

(52) U.S. Cl. CPC C01B 32/186; C23C 16/0281; C23C 16/26; C23C 16/46; H01L 21/02444; H01L 21/02527; H01L 21/0262; H01L 31/1804; H01L 33/0058; C01B 2204/02; C01P 2002/82

(57) ABSTRACT

The present invention relates to methods for the growth of a graphene layer structure on a substrate, wherein the substrate has a first surface for contacting a susceptor and a second surface for the formation of a graphene layer structure, wherein the substrate is a laminate wafer comprising a silicon support providing the first surface and a germanium layer providing the second surface: and opto-electronic devices obtainable therefrom.

The present invention provides methods for the growth of a graphene layer structure on a substrate. In particular, the present invention relates to the growth of a graphene layer structure on a germanium layer of a laminate wafer. More particularly, growth of the graphene layer structure is carried out by CVD. The present invention also provides an opto-electronic device, particularly an opto-electronic device comprising graphene obtainable by a method of the present invention.

Two-dimensional materials, principally graphene, are being heralded as successors to silicon in electronic devices to continue on the delivery of ever-improved devices as the limits of Moore's Law are approached. The observation of a steady growth in the density of transistors in integrated circuits which are based on silicon is expected to reach the 3 nm node around 2022 and the 2 nm node around 2023. Graphene has been the most widely investigated material for the delivery of next generation electronic devices. However, there remains a number of problems with incorporating graphene into device production.

One key problem is the ability to integrate graphene with CMOS compatible manufacture, particularly at wafer scale. Large area wafer scale graphene has been grown for a number of years using catalytic metal substrates of which copper foil is the most common. However, it is well known that metals contaminate the graphene and the necessary transfer processing is not suitable for large scale manufacture due to the damage and reduction in graphene quality which inevitably results. Additionally, such transfer processes lack the consistency required for industrial production.

It is known in the art that graphene may be synthesised, manufactured, formed, directly on non-metallic surfaces of substrates. These include silicon, sapphire and III-V semiconductor substrates. The present inventors have found that the most effective method for manufacturing high-quality graphene, especially directly on such non-metallic surfaces, is that disclosed in WO 2017/029470. This publication discloses methods for manufacturing graphene; principally these rely on heating a substrate held within a reaction chamber to a temperature that is within a decomposition range of a carbon based precursor for graphene growth, introducing the precursor into the reaction chamber through a relatively cool inlet so as to establish a sufficiently steep thermal gradient that extends away from the substrate surface towards the point at which the precursor enters the reactions chamber such that the fraction of precursor that reacts in the gas phase is low enough to allow the formation of graphene from carbon released from the decomposed precursor. Preferably the apparatus comprises a showerhead having a plurality of precursor entry points or inlets, the separation of which from the substrate surface may be varied and is preferably less than 100 mm. The method of WO 2017/029470 is ideally performed using an MOCVD reactor. Whilst MOCVD stands for metal organic chemical vapour deposition due to its origins for the purposes of manufacturing semiconductor materials such as AlN and GaN from metal organic precursors such as AlMe₃ (TMAI) and GaMe₃ (TMGa), such apparatus and reactors are well known and understood to those skilled in the art as being suitable for use with non-metal organic precursors. MOCVD may be used synonymously with metal organic vapour phase epitaxy (MOVPE).

It is ubiquitous in the art to manufacture graphene from methane (CH₄). Methane represents the simplest precursor for graphene growth having a single carbon atom saturated with hydrogen. Methane is an abundant precursor available in suitably high purity for graphene growth. As a gaseous precursor, methane is particularly suitable for use in MOCVD apparatus as well as most other chemical vapour deposition apparatuses. For similar reasons, one of the other most common precursors for graphene growth is acetylene (C₂H₂).

Whilst the method of WO 2017/029470 enables the production of high-quality graphene with excellent uniformity and a constant number of layers (as desired) across its whole area on the substrate without additional carbon fragments or islands, the strict requirements in the art of electronic device manufacture means that there remains a need to further improve the electronic properties of the graphene and to provide methods that are more reliable and more efficient for the industrial manufacture of graphene, particularly large area graphene on non-metallic substrates and even more so for direct graphene growth on CMOS substrates.

It is however known that during the growth of graphene on silicon, directly by CVD, the formation and quality of the graphene may be hindered due to the formation of carbides, which is the formation of covalent carbon-silicon bonds. One concept for addressing both of these issues of providing CMOS compatible graphene growth methods whilst avoiding silicon carbide formation involves use of germanium to provide a growth surface on silicon and CMOS substrates/wafers. Germanium does not readily form carbides leading to higher quality graphene. One problem is that germanium has a melting point of about 940° C. and graphene production directly on germanium, to date, primarily relies on heating the substrate substantially as close to the melting point as possible.

Scientific Reports 6:21773 (2016) “Graphene growth on Ge (100)/Si (100) substrates by CVD method” discloses the synthesis of graphene in an Aixtron® Black-Magic CVD system on (100)-oriented Ge layers deposited by CVD on Si (100) wafers. To ensure optimal temperature conditions, both top and bottom heaters were set simultaneously to achieve a temperature in the range 900° C. to 930° C. Methane was used as a carbon precursor in a mixture of Ar and H₂ in the ratio of 20:1.

Carbon 134, 183-188 (2018) “Early Stage of CVD graphene synthesis on Ge (001) substrate” discloses the deposition of graphene on Ge (001) substrates in an Aixtron® Black-Magic CVD system using CH4 and H₂ as precursor gases and Ar as a carrier gas. The substrate temperature was fixed at 930° C.

Scientific Reports 10:12938 (2020) “Direct growth of graphene on Ge (100) and Ge (110) via thermal and plasma enhanced CVD” relates to the growth of graphene from CH₄ in an Aixtron® Black-Magic CVD system on Ge (100) on a silicon wafer and on a Ge (110) wafer. The temperature was increased until the Ge surface begins to melt and the processing temperature adjusted roughly 10 K for Ge (100) or 30 K for Ge (110). In an effort to reduce the synthesis temperature of graphene on Ge, a plasma is used in PECVD to dissociate the CH₄ precursor. However, PECVD leads to a defective carbon film around and beneath the crystalline flakes of graphene.

US 2011/244662 relates to a method of manufacturing graphene that includes forming a germanium layer on a surface of a substrate, and forming the graphene directly on the germanium layer by supplying carbon-containing gas into a chamber in which the substrate is disposed.

The inventors developed the present invention with the aim to improve the process for manufacturing graphene to enable the integration of high quality graphene with CMOS and CMOS compatible substrates which are based on silicon.

Accordingly, in a first aspect there is provided a method for the growth of a graphene layer structure on a substrate, the method comprising:
providing a substrate on a susceptor in a CVD reaction chamber, wherein the substrate has a first surface for contacting the susceptor and a second surface for the formation of a graphene layer structure;
providing a carbon-containing precursor;
heating the susceptor to achieve a temperature of the second surface sufficient to thermally decompose the precursor and below 940° C.; and
introducing the carbon-containing precursor into the reaction chamber to provide a flow of the precursor across the second surface to thereby form the graphene layer structure on the second surface;
wherein the substrate is a laminate wafer comprising a silicon support providing the first surface and a germanium layer providing the second surface, wherein the germanium layer has a thickness of at least 100 nm; and
wherein the CVD reactor is a cold-walled reactor and the heated susceptor is the only source of heat in the reaction chamber.

In a second aspect, there is provided a method for the growth of a graphene layer structure on a substrate, the method comprising:
providing a substrate on a susceptor in a CVD reaction chamber, wherein the substrate has a first surface for contacting the susceptor and a second surface for the formation of a graphene layer structure;
providing a carbon-containing precursor;
heating the susceptor to achieve a temperature of the second surface sufficient to thermally decompose the precursor and below 940° C.; and
introducing the carbon-containing precursor into the reaction chamber to provide a flow of the precursor across the second surface and to thereby form the graphene layer structure on the second surface;
wherein the substrate is a laminate wafer comprising a silicon support providing the first surface and a germanium layer providing the second surface, wherein the germanium layer has a thickness of 10 nm to 2 μm, preferably 50 to 500 nm; and
wherein the substrate further comprises a barrier layer between the silicon support and the germanium layer, wherein the barrier layer is an inorganic oxide, nitride or fluoride, and preferably is comprised of SiNₓ, SiO₂, Al₂O₃, HfO₂, ZrO₂, YSZ, SrTiO₃, YAIO₃, MgAl₂O₄, CaF₂, AlN or GaN.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

As discussed above, it is known that graphene may be grown directly on germanium layers by CVD methods using the conventional precursor in the art for graphene growth: methane (CH₄). It is essential to work as close to the melting point of the germanium growth surface as possible in view of the particularly high decomposition temperature of methane, and this is set as a single processing temperature and controlled by heaters present both above and below the wafer.

The inventors sought to manufacture graphene using methods such as those disclosed in WO 2017/029470 the contents of which is incorporated herein by reference in its entirety which employ a thermal gradient between the growth surface of the substrate and the point at which the precursor enters the CVD reaction chamber. When seeking to overcome the problem of graphene integration into silicon based electronics (i.e. the deposition of graphene on silicon and/or CMOS wafers and the like resulting in silicon-carbon bonding) by depositing graphene on a germanium layer, the inventors found that the relatively low melting point of germanium of about 940°° C. resulted in particular problems when a heated susceptor, which is beneath the wafer so as to provide the desirably steep thermal gradient for graphene growth, is the only source of heat.

In order to achieve the desired temperature of the upper surface of the wafer (i.e. the growth surface upon which graphene is to be formed), it is necessary to overheat the bottom surface of the wafer which sits in contact with the heated susceptor. The extent of overheating can be substantial such that the temperature of the bottom surface (the first surface as described herein) of the substrate can be, for example, from 50° C. to 200° C. hotter than the temperature of the upper growth surface (the second surface as described herein). By way of example, silicon has a melting point of about 1400° C. which is beyond the processing temperatures which can be achieved in a CVD system and therefore does not cause the same problems.

Whilst this requirement precludes the use of a pure germanium wafer, since the bottom surface would otherwise melt, the presence of the silicon based wafer upon which a germanium layer is provided serves to mitigate the issue of the low melting point of germanium. However, the inventors realised that the diffusion of silicon into the germanium layer due to the solubility of Si in Ge, particularly at the high temperatures used for graphene growth, negated the benefit of a germanium layer since this allowed for the formation of silicon-carbon bonds between the wafer and graphene. The diffusion may also be exacerbated by the temperature anisotropy across the laminate comprising silicon and germanium.

Surprisingly, the inventors discovered that a laminate wafer comprising a germanium layer that is at least 100 nm in thickness is sufficient to prevent diffusion of silicon to the growth surface. The inventors also advantageously found that significantly thinner layers of germanium may be used by employing a barrier layer between the silicon support and the germanium layer, the barrier layer being an inorganic oxide, nitride or fluoride, thereby preventing silicon diffusion to the growth surface. The use of such barrier layers is discussed in more detail below.

In the first aspect, preferably, the germanium layer is no thicker than 3 μm, preferably no thicker than 2.5 μm, preferably no thicker than 2 μm. Preferably, the germanium layer has a thickness of 500 nm to 3 μm, preferably 1 to 2.5 μm and most preferably from 1.5 to 2 μm. Such thicknesses have been found to be suitable to prevent silicon diffusion during graphene growth whilst also not being too thick so as to risk melting of the germanium at the interface of the laminate wafer between the silicon support and the germanium layer, in view of the non-uniform heating.

In accordance with the second aspect, the germanium layer has a thickness of 10 nm to 2 μm, preferably 50 to 500 nm. Together with the thinner germanium layer of at least 10 nm, which may only be up to 500 nm, the substrate further comprises a barrier layer between the silicon support and the germanium layer, wherein the barrier layer is an inorganic oxide, nitride or fluoride.

The present invention relates to methods for the growth of a graphene layer structure on a substrate which may be considered synonymous with synthesising, forming, producing and manufacturing graphene. Graphene is a very well-known two-dimensional material referring to an allotrope of carbon comprising a single layer of carbon atoms in a hexagonal lattice. Graphene and graphene layer, as used herein, refers to one or more monolayers of graphene. Accordingly, the present invention relates to the formation of a monolayer of graphene as well as multilayer graphene (which may be termed a graphene layer structure). Preferably, graphene refers to a graphene layer structure having from 1 to 10 monolayers of graphene. In many subsequent applications, a monolayer of graphene on a substrate is particularly preferred. Accordingly, the graphene manufactured in the method disclosed herein is preferably monolayer graphene in view of the unique electronic properties associated with the “Dirac cone” band structure of a single graphene sheet. Nevertheless, multilayer graphene is preferable for other applications and 2 or 3 layers of graphene may be preferred. Multilayer graphene provides a band gap and also increases electronic and thermal conductivity of the graphene layer.

The methods comprise providing a substrate on a susceptor in a CVD reaction chamber (i.e. the reaction chamber of a CVD reactor). CVD refers a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. Specifically, the methods disclosed herein involve forming graphene by thermal CVD such that decomposition is a result of heating the precursor (specifically via susceptor heating in the present method) rather than, for example, as a result of a plasma in a plasma enhanced chemical vapour deposition (PECVD) process.

In accordance with the first aspect of the present invention, the CVD reactor is a cold-walled reactor and the heated susceptor is the only source of heat in the reaction chamber. In other words, the CVD reaction chamber is a cold-walled reaction chamber and a heater coupled to the substrate is the only source of heat to the chamber when carrying out the method disclosed herein. Such cold-walled reactors are well-known in the art and refer to reactors wherein the substrate itself is heated as opposed to hot-walled reactors wherein the wall(s), such as a quartz tube, are heated to thereby radiate heat into the reaction chamber.

The substrate for use in the methods disclosed herein has a first surface for contacting the susceptor and a second surface for the formation of a graphene layer structure. That is, in providing a substrate on the susceptor of a CVD reactor, the first surface of the substrate is in contact with the susceptor. The second opposing surface of the substrate is therefore that which remains exposed to allow for the deposition of carbon and the formation of graphene during CVD.

Specifically, the substrate is a laminate wafer comprising a silicon support providing the first surface and a germanium layer providing the second surface. Wafer and substrate are common terms in the art and may be used interchangeably. A laminate wafer refers to a wafer (i.e. a substrate for the fabrication of electronic devices) comprising at least two distinct layers, specifically a silicon support which provides the first surface for contacting the susceptor during CVD. Suitable silicon supports may be any conventional silicon based wafers/substrates. The silicon support may be a silicon wafer (that may be optionally doped) or a CMOS wafer. In another embodiment, the silicon support may be SiC or SiGe, i.e. an alloy of silicon and germanium. Preferably, the silicon support is a CMOS wafer, a solar cell (e.g. a silicon solar cell), an LED or an OLED device.

Preferably, the silicon support has a thickness of less than 1.5 mm, preferably less than 800 μm. Thinner wafers result in greater wafer bow during heating, particularly at graphene growth temperatures and the inventors have found that greater heating of the susceptor, and therefore the first surface, is required in order to achieve the desired second surface temperature. Advantageously, the present methods facilitate the use of such thinner wafers despite the greater temperature gradient that results across the laminate wafer/substrate. Preferably, the substrate has a diameter of 2″ (51 mm) or greater, preferably 4″ (100 mm) or greater, preferably 6″ (150 mm) or greater, and preferably 8″ (200 mm) or greater. As with the thinner wafers, larger diameter wafers also have more bow increasing the heating required of the susceptor and the first surface and resulting temperature difference between the first and second surfaces. Thus, for larger wafers, the use of the invention becomes more important.

The second layer is a germanium layer consisting of elemental germanium and provides the upper surface upon which graphene is formed. As described herein, the laminate wafer may preferably comprise further layers. In accordance with the first aspect, the germanium layer has a thickness of at least 100 nm which the inventors have found enables the production of high quality graphene suitable for CMOS integration where the heated substrate is the only source of heat during CVD.

Preferably, the second surface has a surface roughness of less than 0.5 nm, preferably less than 0.2 nm and more preferably less than 0.1 nm. Surface roughness may be measured using conventional techniques as the arithmetic average (Ra). In one embodiment, the surface roughness may be achieved by an in situ surface treatment to remove native oxides as described herein. Alternatively, the desirably smooth surface can be achieved through chemical mechanical polishing. The preferred Ra facilitates the formation of higher quality graphene with fewer defects.

It is also particularly preferred that the germanium layer is an epitaxial germanium layer. Epitaxially grown germanium typically provides a high degree of crystallinity which aids in graphene formation on the surface thereof by the method disclosed herein. For example, the crystallographic orientation of the surface of the germanium layer may be (110), (001) or (111). Such epitaxial layers are readily distinguishable from layers grown by other methods, for example, where germanium is deposited on a silicon support by sputtering. Epitaxial layers of germanium-on-silicon are commercially available though suitable laminate wafers may also be prepared by those skilled in the art as described further herein.

The methods further comprise providing a carbon-containing precursor. The most common carbon-containing precursor in the art for graphene growth is methane (CH₄). As described herein, each aspect of the present invention preferably uses an organic compound, that is, a chemical compound, or molecule, that contains a carbon-hydrogen covalent bond and therefore comprises at least one carbon atom, preferably two or more carbon atoms. Such precursors with two or more carbon atoms generally have a lower decomposition temperature than methane which advantageously allows the growth of graphene at lower temperatures when using the method described herein. Preferably, the precursor is a liquid when measured at 20° C. and 1 bar of pressure (i.e. under standard conditions according to IUPAC). Accordingly, the precursor has a melting point that is below 20° C., preferably below 10° C., and has a boiling point above 20° C., preferably above 30° C. Liquid precursors are simpler to store and handle when compared to gaseous precursors which typically require high pressure cylinders. Due to their relatively reduced volatility when compared to gaseous precursors, they present a lower safety risk during large scale manufacture. Increasing the molecular weight of the compounds beyond about C₁₀, particularly beyond about C₁₂, typically reduces their volatility and suitability for CVD growth of graphene on non-metallic substrates (though graphene can be produced from solid organic compounds). Accordingly, the carbon-containing precursor used in the methods may be a C₁-C₁₂ organic compound. Preferably, the organic compound consists of carbon and hydrogen and, optionally, oxygen, nitrogen and/or a halogen (i.e. fluorine, chlorine, bromine and/or iodine).

The methods further comprise heating the susceptor to achieve a temperature of the second surface sufficient to thermally decompose the precursor and below 940° C. Any standard technique for susceptor heating may be used which in turn results in the heating of the substrate which is provided thereon. The susceptor may comprise one or more recesses for retaining one or more substrates. The means for susceptor heating being a customary component of a CVD reactor. For example, the susceptor may be heated by radio frequency (RF) radiation, a resistive heating element or external lamps, coupled to the susceptor. The temperature required to heat the susceptor is typically much greater than the resulting temperature of the exposed upper growth surface of the substrate such that there is a temperature gradient across the thickness of the substrate. Accordingly, the susceptor may be heated to a temperature greater than 940° C. such that the temperature of the second surface provided by the germanium layer is less than 940° C. The susceptor temperature, may be set using any conventional means in the art, for example, using a thermocouple positioned on or directly below the susceptor. Typically, the temperature difference between the susceptor, for example as measured by a thermocouple, and the second surface is at least 250° C. and may be at least 300° C., at least 350° C. or even at least 400° C. Typically, the surface temperature of the substrate (i.e. the temperature of the second surface provided by the germanium layer) is monitored and measured using any standard technique and apparatus, for example by pyrometry using a pyrometer.

The inventors have found that the use of organic compounds with two or more carbon atoms whose decomposition temperature is lower than methane advantageously facilitates the formation of high quality graphene using the method described herein. Accordingly, in a preferred embodiment, the temperature of the second surface is below 930° C., preferably below 920° C., preferably, below 910° C., even more preferably below 900° C. The temperature required for decomposition of a given precursor may be readily known or can be readily ascertained by the skilled person. Nevertheless, it is preferred that the temperature of the second surface is at least 700° C., preferably at least 750° C. to promote improved surface kinetics and encourage high quality crystal formation. Accordingly, the temperature of the second surface may be from 700° C. to 940° C., preferably 700° C. to 900° C., preferably from 750° C. to 900° C.

The methods further comprise introducing the carbon-containing precursor into the reaction chamber to provide a flow of the precursor across the second surface to thereby form the graphene layer structure on the second surface. As is conventional for CVD processes, the precursor is introduced into the reaction chamber in the gas phase and/or suspended in a gas. In a preferred embodiment of the present invention, the precursor is introduced into the CVD reaction chamber as a mixture with a carrier gas. Carrier gases are well known in the art and may also be referred to as a dilution gas or a diluent. Carrier gases typically include inert gases such as noble gases, and in the case of graphene growth, hydrogen gas. Accordingly, the carrier gas is preferably one or more of hydrogen (H₂), nitrogen (N₂), helium (He), and argon (Ar). More preferably the carrier gas is one of nitrogen, helium and argon or the carrier gas is a mixture of hydrogen and one of nitrogen, helium and argon.

The heated substrate, heated in excess of the decomposition temperature of the precursor, results in the decomposition of the precursor as the precursor flows across the surface of the substrate. This decomposition liberates carbon from the carbon-containing precursor which crystallises on the second surface of the germanium layer providing the graphene layer structure.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface. Accordingly, such an embodiment involves a “vertical” arrangement whereby the plane containing the precursor entry points is substantially parallel to the plane of the substrate surface.

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 75° C., preferably less than 60° C., such as from 40° C. to 60° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to within a decomposition range of the precursor, generates a sufficiently steep thermal gradient extending from the substrate surface to the precursor entry points to allow graphene formation on the substrate surface. As disclosed in WO 2017/029470, very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor.

Consequently, in a particularly preferred embodiment wherein the method of the present invention involves using a method as disclosed in WO 2017/029470, the method comprises:
providing a substrate on a susceptor in a CVD reaction chamber in a close-coupled reaction chamber, the close-coupled reaction chamber having a plurality of cooled inlets arranged so that, in use, the inlets are distributed across the second surface of the substrate and have constant separation from the substrate;
cooling the inlets (i.e. the precursor entry points);
heating the susceptor to achieve a temperature of the second surface sufficient to thermally decompose the precursor and below 940° C.;
introducing the carbon-containing precursor in a gas phase and/or suspended in a gas through the inlets and into the CVD reaction chamber;
wherein the heating provides a thermal gradient between the substrate surface and inlets that is sufficiently steep to allow the formation of the graphene layer structure from carbon released from the decomposed precursor on the germanium layer of the substrate; and
wherein the constant separation is less than 100 mm, preferably less than 25 mm, even more preferably less than 10 mm.

The inventors have advantageously found that the presence of a barrier layer in the form of an inorganic oxide or nitride, which may also be referred to as ceramic materials which are well-known solid state materials, serves to prevent the diffusion of silicon from the silicon support through to the germanium layer and therefore preventing the formation of silicon-carbon bonds during graphene growth by CVD.

Preferably, the inorganic oxide, nitride or fluoride, is a metal oxide or metal nitride or metal fluoride. Preferably, the barrier layer is an inorganic oxide or nitride, and preferably is comprised of SiNₓ, SiO₂, Al₂O₃, HfO₂, ZrO₂, YSZ, SrTiO₃, AlN or GaN. Silicon nitride and aluminium nitride are preferred inorganic nitrides and the barrier is preferably comprised of SiNₓ, SiO₂, Al₂O₃, HfO₂, ZrO₂, yttrium stabilised zirconia (YSZ) or AlN. The presence of such inorganic layers which restrict the migration of silicon to the growth surface advantageously enables thinner germanium layers to be used. In view of the aforementioned benefits associated with CVD growth in a CVD reactor wherein the heated susceptor is the only source of heat to the chamber, the method of the second aspect also preferably is carried out in such a cold-walled reactor. Without wishing to be bound by theory, the inventors believe that the use of a barrier layer enables growth of high quality graphene on particularly thin germanium layers in embodiments which nevertheless comprise heating with a second heater, such as a top heater for directly heating the upper growth surface of the substrate.

Preferably, the germanium layer has a thickness of 20 nm to 1 μm, preferably 50 to 500 nm and most preferably from 75 to 250 nm when combined with a barrier layer in the substrate. However, in some embodiments, the germanium layer is preferably thick in accordance with the first aspect where the substrate may also preferably further comprise a layer of SiNₓ, SiO₂, Al₂O₃, HfO₂, ZrO₂, YSZ, SrTiO₃, YAIO₃, MgAl₂O₄, CaF₂, AlN or GaN between the silicon support and the germanium layer, for example SiNₓ, SiO₂, Al₂O₃, HfO₂, ZrO₂ or YSZ. In any aspect, the barrier layer is preferably SiNₓ, AlN, SiO₂ or Al₂O₃, preferably SiNₓ, SiO₂ or Al₂O₃, preferably SiNₓ or SiO₂. Such a barrier layer may be deposited by any conventional technique such as atomic layer deposition or by physical vapour deposition such as e-beam or evaporation. Preferably, deposition is carried out by ALD since such a technique allows for the deposition of conformal layers at the desirably thin thicknesses.

Preferably, the barrier layer has a thickness of less than 50 nm, preferably less than 20 nm and more preferably less than 10 nm. The inventors were surprised to find that such thin barriers layers are effective at preventing the diffusion of silicon atoms into the germanium layer which otherwise readily occurs where the germanium layer is provided in direct contact with the silicon support. Preferably, the thickness of the barrier layer is at least 1 nm, preferably at least 2 nm. Accordingly, the presence of a barrier layer is particularly advantageous for the integration of graphene into CMOS devices and associated fabrication processes.

Preferably, the substrate is formed in situ in the reaction chamber by the deposition of germanium on a wafer comprising the silicon support (preferably epitaxial deposition). In one embodiment, the germanium is deposited directly on the silicon support and in accordance with the first aspect, the germanium layer will have a thickness of at least 100 nm in order to prevent silicon diffusion to the growth surface during graphene growth. Advantageously, such a method allows for the disposition of both germanium and graphene in the same CVD reaction chamber.

In another preferred embodiment, before the deposition of germanium on the wafer, there is an in situ step of forming a barrier layer on the silicon support. Accordingly, the germanium layer is then deposited on the surface of the barrier layer (which is formed of an inorganic oxide or nitride such as SiO₂). In accordance with the second aspect, the germanium layer may then be thinner than 100 nm as required in the first aspect, i.e. from 10 nm to 100 nm thick, though thicker germanium layers may still be employed.

Alternatively, in a preferred embodiment, the barrier layer is provided on the silicon support prior to placing the wafer into the CVD reaction chamber. For example, a silicon or CMOS wafer may be supplied with a native oxide on the surface which may then serve as the barrier layer upon which germanium may be deposited. Equally, suitable laminates may be commercially available with the desired barrier layer, for example silicon nitride.

In another preferred embodiment, the method further comprises a step of treating the substrate under a flow of hydrogen and/or argon (preferably hydrogen) to remove any native oxide present. In other words, the second surface of the laminate wafer may be treated with a flow of hydrogen and/or argon to remove the native oxide present on the germanium surface. Equally, the method may preferably comprise treating a wafer comprising the silicon support prior to germanium deposition under a flow of hydrogen and/or argon to remove the native oxide present on the silicon surface. Thus, in one preferred embodiment, a hydrogen treatment to remove native oxide may be applied to both the surface of the silicon support and the germanium layer where the germanium layer is not formed in situ in order to provide the substrate in accordance with the present methods. Advantageously, the in situ formation of a germanium as described above prevents surface contamination and the formation of an oxide layer prior to graphene growth thereby avoiding the need to carry out the additional hydrogen treatment.

As discussed above, the methods described herein preferably use a carbon-containing precursor that is an organic compound comprising two of more carbon atoms, i.e. a C₂₊ organic compound. In accordance with at least the first aspect wherein a thicker germanium layer of at least 100 nm provides the second surface of the substrate, the inventors have found that C₃₊ organic compounds are particularly preferable for the formation of graphene at lower temperatures thereby further reducing the risk of silicon diffusion to the growth surface. Preferably, the carbon-containing precursor is a C₃-C₁₂ organic compound consisting of carbon and hydrogen and, optionally, oxygen, nitrogen and/or a halogen. As described herein, a Cn organic compound refers to one comprising “n” carbon atoms and optionally one or more further hetero atoms oxygen, nitrogen and/or a halogen. Preferably, the organic compound comprises at most one heteroatom as such organic compounds are typically more readily available in high purity, for example ethers, amines, and haloalkanes.

Where the substrate comprises a barrier layer as described herein, which enables the use of thin germanium layers, the carbon-containing precursor is preferably a C₁-C₁₂ organic compound consisting of carbon and hydrogen and, optionally, oxygen, nitrogen and/or a halogen, preferably a C₂-C₁₂ organic compound. Accordingly, standard precursors such as methane and acetylene, if used, are preferably used to form graphene on the germanium growth surface of a substrate that comprises a barrier layer in view of the higher temperatures preferred to heat the substrate in order to achieve sufficient thermal decomposition of such small molecule precursors (i.e. a second surface temperature of from about 900° C. to about 940° C.).

Nevertheless, in any aspect, the carbon-containing precursor is preferably a C₃-C₁₀ organic compound consisting of carbon and hydrogen and, optionally, oxygen, nitrogen and/or a halogen, even more preferably a C₆-C₉ organic compound. In a preferred embodiment, the precursor does not comprise a heteroatom, such that the precursor consists of carbon and hydrogen. In other words, preferably the carbon-containing precursor is a hydrocarbon, preferably an alkane.

It is also preferable that the organic compound comprise at least two methyl groups (—CH₃).

Particularly preferred organic compounds for use as carbon-containing precursors, and methods of forming graphene therefrom by CVD, are described in UK Patent Application No. 2103041.6, the contents of which is incorporated herein in its entirety. The inventors have found that when forming graphene directly on non-metallic substrates, precursors beyond the traditional hydrocarbons methane and acetylene allow for the formation of even higher quality graphene. Preferably, the precursor is a C₄-C₁₀ organic compound, more preferably the organic compound is branched such that the organic compound at least three methyl groups.

Without wishing to be bound by theory, the inventors believe that heavier organic compounds (i.e. those greater than C₁₂, or greater than C₁₀, and/or those which are solid under standard conditions) provide a “less pure” source of CH₃ radicals. With an increase in size and complexity of the organic compound there is an increase in the number of decomposition pathways and the possibility of a greater range of byproducts which can lead to graphene defects. The organic compounds as described herein provide a balance of being large enough to deliver the required, and a desirably high fraction of, methyl groups under pyrolysis. The organic compounds are however small enough to be simple to purify, particularly where the precursor is liquid, and have a relatively simple pyrolysis chemistry with limited decomposition pathways. Furthermore, unlike heavier compounds, they do so not readily condense within the reactor plumbing which is a particular disadvantage for the industrial production of graphene due to the greater risk of reactor downtime.

The present invention also provides, in a third aspect, a method for the growth of a graphene layer structure on a substrate, the method comprising:
providing a substrate on a susceptor in a CVD reaction chamber, wherein the substrate has a first surface for contacting the susceptor and a second surface for the formation of a graphene layer structure;
providing a carbon-containing precursor;
heating the susceptor to a temperature of greater than 940° C. to achieve a temperature of the second surface sufficient to thermally decompose the precursor and below 940° C.; and
introducing the carbon-containing precursor into the reaction chamber to provide a flow of the precursor across the second surface to thereby form the graphene layer structure on the second surface;
wherein the substrate is a laminate wafer comprising a silicon support providing the first surface and a germanium layer providing the second surface, wherein the germanium layer has a thickness of at least 100 nm.

As described herein, particularly with regards to the first aspect, the temperature of the susceptor, and therefore of the first surface, being greater than the melting point of germanium yet the second surface provided by the germanium layer being below such a temperature of 940° C., thereby providing a non-uniform temperature profile across the laminate wafer, was found to promote silicon migration from the silicon support to the second surface. Accordingly, a 100 nm thick germanium layer is sufficient to prevent such diffusion in the method of the third aspect wherein the temperatures of the first and second surface of the substrate differ. As discussed herein, the temperature difference between the susceptor and second surface may preferably be at least 250° C., at least 300° C., at least 350° C. or even at least 400° C. Typically, the temperature difference between the first and second surfaces will be from 50° C. to 200° C.

In a final aspect of the present invention there is provided an opto-electronic device comprising a graphene electrode obtainable by any method described herein. Preferably, the device is a solar cell, light-emitting diode (LED), organic light emitting diode (OLED), electro-optic modulator (EOM), photodetector or diode (such as a photodiode). Preferably, the graphene electrode is obtained by a method as described herein, the method may further comprise a patterning step so as to shape the graphene layer structure, for example by laser or plasma etching.

Accordingly, there is provided an opto-electronic device comprising graphene on a germanium layer of a laminate wafer wherein the germanium layer is on a silicon support. Preferably, the opto-electronic device comprises a silicon support with an inorganic oxide or nitride barrier layer.

### FIGURES

The present invention will now be described further with reference to the following non-limiting Figures, in which:

FIG. 1 is a Raman spectrum of graphene grown in accordance with the present invention onto epitaxial germanium on silicon.

FIG. 2 is X-ray photoelectron depth profile data generated by etching from the top downwards through a wafer comprising graphene grown in accordance with the present invention onto epitaxial germanium on silicon.

### EXAMPLES

Wafers consisting of 2 μm epitaxial Ge on Si are positioned upon a silicon carbide-coated graphite susceptor within an MOCVD reactor chamber. The reactor chamber itself is protected in an inert atmosphere within a glovebox. The reactor is then sealed closed using a vacuum cavity which separates the reactor interior from the glovebox ambient by a double O-ring. The reactor is purged under a flow of nitrogen, argon or hydrogen gas at a rate of 10,000 to 60,000 sccm. The susceptor is rotated at a rate of 40 to 60 rpm. The pressure within the reactor chamber is reduced to 30 to 800 mbar. An optical probe is used to monitor the wafer reflectivity and temperature during growth—with the wafers still in their unheated state, they are rotated under the probe in order to establish a baseline signal. The wafers are then heated using resistive heater coils positioned beneath the susceptor to a setpoint of from 850 to 1000° C. at a rate of 0.5 to 2.0 K/s to achieve a surface temperature of the wafer, i.e. that of the germanium layer, of from 800 to 940° C. The wafers are optionally baked under flow of hydrogen gas for from 10 to 60 min, after which the ambient gas is switched to nitrogen or argon and the pressure is ramped to the conditions for growth. The wafer is annealed at the growth temperature and pressure for a period of from 5 to 10 min, after which a hydrocarbon precursor is admitted to the chamber. This is transported from its liquid state in a bubbler by passing a carrier gas (nitrogen, argon or hydrogen) through the liquid which is held under constant temperature and pressure. The vapour enters a gas mixing manifold and proceeds to the reactor chamber through a showerhead via a multitude of small inlets commonly referred to in the art as plenums/plena, which guarantees uniform vapour distribution and growth across the surface of the wafers. The wafers are exposed to the hydrocarbon vapour under constant flow, pressure and temperature for a duration of 1,800 to 10,800 s at which point the precursor supply valve is shut off. The wafers are then cooled under continuing flow of nitrogen, argon or hydrogen gas at a rate of from 2 to 4 K/min. Once the wafer temperature reaches below 200° C., the chamber is pumped to vacuum and purged with inert gas. The rotation is stopped and the heaters are shut off. The reactor chamber is opened and the graphene-coated wafers are removed from the susceptor once the heater temperature reaches below 150° C.

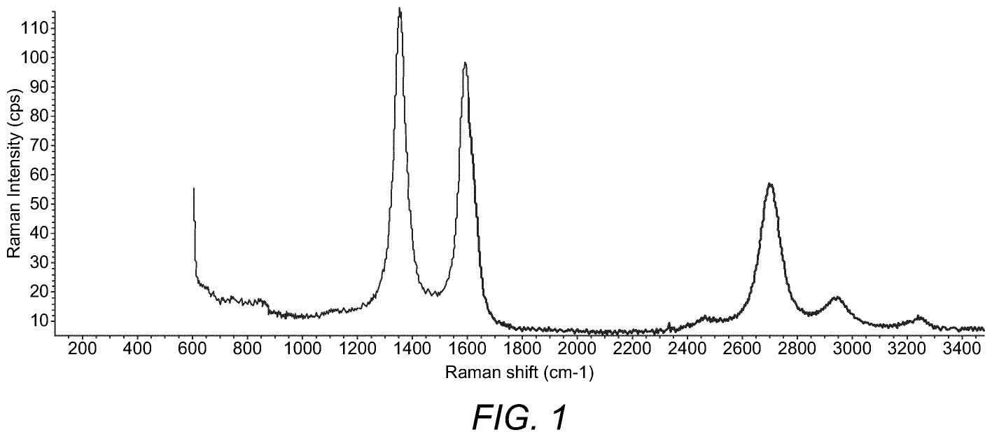

The graphene formed was then characterised using standard techniques including Raman spectroscopy as shown in FIG. 1.

FIG. 1 is a Raman spectrum confirming the growth of graphene onto epitaxial germanium (about 2 μm thick) on silicon. The three main peaks are characteristic of graphene.

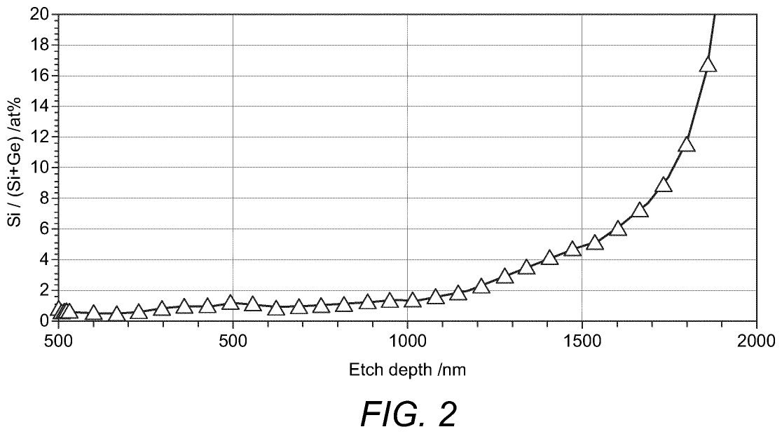

FIG. 2 is X-ray photoelectron depth profile data for a wafer with a top layer of graphene having been grown on 2 μm epitaxial germanium directly on a silicon wafer, following the process described in the Example.

The profile data is produced by etching the wafer using a rastering Ar ion beam, starting from the graphene layer and etching downwards into the 2 μm-thick germanium layer towards the silicon layer. The diffusion of Si into the Ge layer is measured at levels in the stack between periods of etching. Data were fitted from measurements of the Si2p and Ge3d photoelectron peaks. The etch depth was calculated retrospectively based on the etch time and the nominal thickness of the Ge layer.

In this specific example, at etch depths up to 1000 nm into the 2 μm-thick Ge layer, the level of silicon diffusion into the germanium is shown to be effectively zero (the minimal levels shown in FIG. 2 in this range is noise from the profiling technique, i.e. less than about 1.5 at %, may be considered noise). However, at etch depths above 1000 nm, the diffusion of Si into the Ge layer is evident and trends sharply upwards as the etch depth reaches the limits of the germanium layer and approaches the underlying silicon layer. This example demonstrates that silicon diffusion is particularly high at etch depths above 1900 nm. Consequently, a germanium layer thickness of greater than 100 nm can be sufficient to significantly reduce the silicon content at the growth surface of the wafer. In the present example, a silicon content of less than about 20 at % can be achieved. Nevertheless, greater than 500 nm is preferable since the silicon content is significantly reduced to values of less than about 5 at %. As will be appreciated, for longer graphene growth times, it will be preferred that the germanium layer is thicker in view of the expected increase in silicon diffusion whilst the wafer is held at high temperatures for a longer period of time. Equally, for shorter graphene growth times, silicon diffusion may be effectively prevented by 500 nm of germanium.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1-4. (canceled)

5. A method for the growth of a graphene layer structure on a substrate, the method comprising:
providing a substrate on a susceptor in a CVD reaction chamber, wherein the substrate has a first surface for contacting the susceptor and a second surface for the formation of a graphene layer structure;
providing a carbon-containing precursor;
heating the susceptor to achieve a temperature of the second surface sufficient to thermally decompose the precursor and below 940° C.; and
introducing the carbon-containing precursor into the reaction chamber to provide a flow of the precursor across the second surface and to thereby form the graphene layer structure on the second surface;
wherein the substrate is a laminate wafer comprising a silicon support providing the first surface and a germanium layer providing the second surface, wherein the germanium layer has a thickness of 10 nm to 2 μm;
wherein the substrate further comprises a barrier layer between the silicon support and the germanium layer, wherein the barrier layer is an inorganic oxide, nitride or fluoride;
wherein the barrier layer has a thickness of less than 50 nm; and
wherein the CVD reactor is a cold-walled reactor and the heated susceptor is the only source of heat in the reaction chamber.

6. The method according to claim 5, wherein the carbon-containing precursor is a C₁-C₁₂ organic compound consisting of carbon and hydrogen and, optionally, oxygen, nitrogen and/or a halogen.

7. The method according to claim 5, wherein the germanium layer has a thickness of 20 nm to 1 μm.

8. (canceled)

9. The method according to claim 5, wherein the carbon-containing precursor is a C₃-C₁₀ organic compound consisting of carbon and hydrogen and, optionally, oxygen, nitrogen and/or a halogen.

10. The method according to claim 5, wherein the carbon-containing precursor is a hydrocarbon.

11. The method according to claim 5, wherein a temperature difference between the susceptor and the second surface is at least 250° C.

12. The method according to claim 5, wherein the second surface has a surface roughness of less than 0.5 nm.

13. The method according to claim 5, wherein the graphene layer structure is a monolayer.

14. The method according to claim 5, wherein the substrate has a diameter of 2″ (51 mm) or greater.

15. The method according to claim 5, wherein the silicon support is a CMOS wafer, a solar cell, an LED or an OLED device.

16. The method according to claim 5, wherein the silicon support has a thickness of less than 1.5 mm.

17. The method according to claim 5, wherein the temperature of the second surface is below 900° C.

18. The method according to claim 5, wherein the substrate is formed in situ in the reaction chamber by the deposition of germanium on a wafer comprising the silicon support.

19. The method according to claim 18, wherein before the deposition of germanium on the wafer, there is an in situ step of forming a barrier layer on the silicon support.

20. The method according to claim 5, wherein the method further comprises a step of treating the substrate under a flow of hydrogen and/or argon to remove any native oxide present.

21. (canceled)

22. The method according to claim 5, wherein the silicon support has a thickness of less than 800 μm.

23. The method according to claim 5, wherein the barrier layer is comprised of SiNₓ, Al₂O₃, HfO₂, ZrO₂, YSZ, SrTiO₃, YAIO₃, MgAl₂O₄, CaF₂, AlN or GaN.

24. The method according to claim 5, wherein the barrier layer has a thickness of at least 2 nm.

25. The method according to claim 5, wherein the temperature of the second surface is at least 700° C.

26. The method according to claim 5, wherein the carbon-containing precursor is a C₆-C₉ organic compound consisting of carbon and hydrogen and, optionally, oxygen, nitrogen and/or a halogen.
